(19) United States
(12) Patent Application Publication
(10) Pub. No.: US 2011/0181448 A1
(43) Pub. Date: Jul. 28, 2011

(54) LOSSLESS COMPRESSION

(76) Inventor: Veeresh Rudrapa Koratagere, Karnataka (IN)

(21) Appl. No.: 12/867,051

(22) PCT Filed: Sep. 30, 2009
(86) PCT No.: PCT/IN2009/000538

§ 371 Date: Aug. 11, 2010

(30) Foreign Application Priority Data
Oct. 15, 2008 (IN) 2512/CHE/2008

(51) Int. Cl. H03M 7/34

(52) U.S. Cl. 341/51

(57) ABSTRACT

Embodiments of the invention include a method and system for data compression which includes receiving as input a data stream, the data stream comprising a sequence of symbols, identifying the first symbol in the data stream, identifying positions in the data stream where the first symbol is repeated, encoding all position in the data stream representing the first symbol and repeating the process until all symbols in the data stream are encoded. The encoding is performed using a binomial encoding technique, where the binomial values are computed and summed thereby achieve better lossless compression.

### PRIORITY DETAILS

This application claims priority of previously filed application number 2510/CHE/2008, titled “Content Encoding” filed on Oct. 15, 2008, 2511/CHE/2008, titled “Loseless Content Encoding” filed on Oct. 15, 2008 and 2512/CHE/2008 titled “Loseless Compression” filed on Oct. 15, 2008 at the Indian Patent Office, the contents of which are herein incorporated in entirety by reference.

### TECHNICAL FIELD

Embodiments of the invention generally relates to encoding/compression of content, and more particularly to using an efficient encoding/compression technique for lossless compression.

### BACKGROUND

Various methods of compressing data have been developed over the past years. Because of the increased use of computer systems, requirements for storage of data have consistently increased. Consequently, it has been desirable to compress data for the purpose of speeding both transmission and storage of the data. Of the various techniques know for data compression, one of the techniques that is widely used is run length encoding.

Huffman coding and arithmetic coding are the most popular statistical encoding techniques. Huffman coding is an entropy encoding algorithm used for lossless data compression. The term refers to the use of a variable-length code table for encoding a source symbol (such as a character in a file) where the variable-length code table has been derived in a particular way based on the estimated probability of occurrence for each possible value of the source symbol.

Huffman coding uses a specific method for choosing the representation for each symbol, resulting in a prefix code (sometimes called “prefix-free codes”) (that is, the bit string representing some particular symbol is never a prefix of the bit string representing any other symbol) that expresses the most common characters using shorter strings of bits than are used for less common source symbols. Huffman was able to design the most efficient compression method of this type: no other mapping of individual source symbols to unique strings of bits will produce a smaller average output size when the actual symbol frequencies agree with those used to create the code. A method was later found to do this in linear time if input probabilities (also known as weights) are sorted.

For a set of symbols with a uniform probability distribution and a number of members which is a power of two, Huffman coding is equivalent to simple binary block encoding, e.g., ASCII coding. Huffman coding is such a widespread method for creating prefix codes that the term “Huffman code” is widely used as a synonym for “prefix code” even when such a code is not produced by Huffman's algorithm.

Although Huffman coding is optimal for a symbol-by-symbol coding with a known input probability distribution, its optimality can sometimes accidentally be over-stated. For example, arithmetic coding and LZW coding often have better compression capability. Both these methods can combine an arbitrary number of symbols for more efficient coding, and generally adapt to the actual input statistics, the latter of which is useful when input probabilities are not precisely known or vary significantly within the stream.

Without a way to provide an improved method and system of compressing data, the promise of this technology may never be fully achieved.

### SUMMARY

Embodiments of the invention relates generally to a method and system for data compression where when an input data stream which contains a sequence of symbols is received, receiving as input a data stream, the data stream comprising a sequence of symbols, identifying the first symbol in the data stream, identifying positions in the data stream where the first symbol is repeated, encoding all position in the data stream representing the first symbol, repeating the method steps until the entire data stream is encoded. Once the first symbol has been encoded using preferably a binomial coefficient, the remaining symbols of the data stream form a reduced sequence. The method is repeated for the reduced sequence, and all symbols encoded until the entire data stream is encoded.

In one embodiment, the method disclosed as embodiments of the invention may be implemented by one or more computer programs. The computer programs may be stored on a computer-readable medium. The computer-readable medium may be a tangible medium, such as a recordable data storage medium, or an intangible medium, such as a modulated carrier signal. Still other advantages, aspects, and embodiments of the disclosure will become apparent by reading the detailed description that follows, and by referring to the accompanying drawings.

### BRIEF DESCRIPTION OF THE DRAWINGS

The drawings referenced herein form a part of the specification. Features shown in the drawing are meant as illustrative of only some embodiments of the invention, and not of all embodiments of the invention, unless otherwise explicitly indicated, and implications to the contrary are otherwise not to be made.

FIG. 1 is an exemplary illustration of a block diagram illustrating the manner in which the compression/decompression techniques of the disclosure may be employed;

FIG. 2 is an exemplary embodiment of a block diagram further defining the manner in which the disclosure may be employed;

FIG. 3 is an exemplary embodiment of a method illustrating the manner in which the disclosure may be employed; and

FIG. 4 is an exemplary embodiment of a system diagram of a computer system on which at least one embodiment of the disclosure may be implemented.

### DETAILED DESCRIPTION

In the following detailed description of exemplary embodiments of the invention, reference is made to the accompanying drawings that form a part hereof, and in which is shown by way of illustration specific exemplary embodiments in which the invention may be practiced. These embodiments are described in sufficient detail to enable those skilled in the art to practice the invention. Other embodiments may be utilized, and logical, mechanical, and other changes may be made without departing from the spirit or scope of the present invention. The following detailed description is, therefore, not to be taken in a limiting sense, and the scope of the present invention is defined only by the appended claims.

Embodiments of the invention related a method and system for data compression, which includes receiving as input a data stream, the data stream comprising a sequence of symbols, identifying the first symbol in the data stream, identifying positions in the data stream where the first symbol is repeated, encoding all positions in the data stream representing the first symbol, repeating the method steps defined above until the entire data stream is encoded.

In a further embodiment, the method includes encoding comprises computing a binomial value for each of the repetitive symbols. The binomial value for each of the repetitive symbols is computed from the sequence length and the position of the first symbol and each of the repetitive symbols in the sequence. The binomial value of the first symbol and each of the repetitive symbols is summed. The binomial value for each of the unique symbols in the sequence is computed and summed. The total sum of the binomial value is computed. The encoding comprises the total number of symbols in the sequence, the symbol of the sequence for which the binomial value is computed and the binomial value.

Yet a further embodiment of the invention includes a system configured to perform the method as disclosed above, especially when the method is operational on the system, and such a system for example may include an electronic device such as a computer system, laptop, etc and may also include portable electronic device such as PDA's, mobile phones, tablet PC's etc.

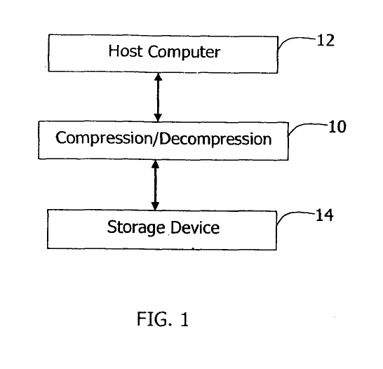

FIG. 1 is an exemplary embodiment of a block diagram illustrating the manner in which the compression/decompression 10 system of the disclosure may be employed in the transfer of data from a host computer 12 to a storage device 14 and vice versa. Although FIG. 1 illustrates one implementation of the disclosure, and it should be apparent to one skilled in the art that the disclosure can also be employed to compress and/or decompress data in any data translation or transmission system desired. For example, the disclosure may be used to compress and/or decompress data in a data transmission system for a facsimile system between two remote locations. Additionally, the disclosure may be used for compressing and/or decompressing data during transmission of data within a computer system.

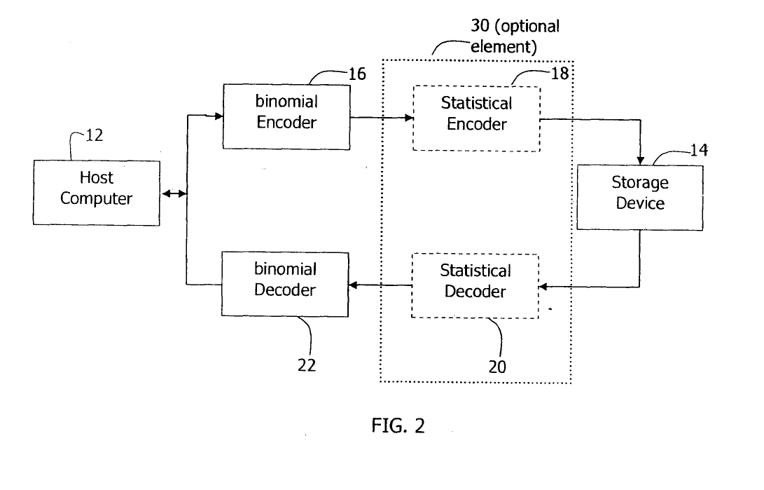

FIG. 2 is an exemplary embodiment of a block diagram illustrating the manner of compression and decompression used in an embodiment of the invention. Compression is accomplished, in accordance with the disclosure, by encoding in an encoder 16. The encoded data produced at the output of encoder 16 in one embodiment may be coupled to a statistical encoder 18, to further compress any remaining symbols in the data stream. The statistical encoder 18 is illustrated in dotted line, indicating that after performing encoding, based on the binomial encoding process, it is not necessary to perform statistical encoding on the data, as the binomial encoding process is an efficient lossless encoding process. The decoding process of embodiments of the invention is accomplished by first statistically decoding the statistical encoded data in statistical decoder 20, if statistical encoding has occurred. The statistical decoded data from statistical decoder 20 is then decoded in decoder 22. Encoder 16 comprises the first stage in the compression process. Encoder 16 scans the data for characters which repeat themselves in the data stream from host computer 12 and encodes them using a technique called encoding by computing binomial values/coefficients as will be discussed below. The statistical encoder 18 and the statistical decoder 22 are optional elements in the system and have therefore been represented in a dashed block 30. The binomial encoding and decoding can be performed efficiently without the statistical encoder and/or the statistical decoder.

Data stream from the host computer 12 is encoded using the binomial encoding technique at the encoder 16. Encoder 16 first receives the input data from host computer 12. The input data received at the Encoder 16 contains a sequence of symbols. Consider sequence “ABARAYARANBARRAYBRAN”, which is provided as input stream to encoder 16. The sequence has a length of 20. The first symbol in the sequence is “A”. In the data stream provided as input to encoder there are 8 such occurrences of “A” in the sequence. For each of these positions for the symbol “A,” the binomial values are computed in the sequence as follows, the 8^{th} “A” is at the 20^{th} position and so on. The binomial values for each of the symbols “A” occurring in the data stream is computed using

$$E ( A 8 ) = ( \begin{matrix}20 \\ 8\end{matrix} ) = 125970 ;$$

Similarly for the other 7 “A”, the binomial value is computed as

$$E ( A 7 ) = ( \begin{matrix}18 \\ 7\end{matrix} ) = 31824 ;$$

$$E ( A 6 ) = ( \begin{matrix}16 \\ 6\end{matrix} ) = 8008 ;$$

$$E ( A 5 ) = ( \begin{matrix}14 \\ 5\end{matrix} ) = 2002 ;$$

$$E ( A 4 ) = ( \begin{matrix}12 \\ 4\end{matrix} ) = 495 ;$$

$$E ( A 3 ) = ( \begin{matrix}9 \\ 3\end{matrix} ) = 84 ;$$

$$E ( A 2 ) = ( \begin{matrix}6 \\ 2\end{matrix} ) = 15 ;$$

$$E ( A 1 ) = ( \begin{matrix}2 \\ 1\end{matrix} ) = 2 ;$$

Encoding of the symbol “A” in encoder 16 can now be computed as follows—

$$E ( A ) = ( \begin{matrix}( l + 1 ) \\ t\end{matrix} ) - {\sum }_{i = 1}^{t} E ( Ai ) ,$$

where “t” is the number of “A” in the sequence

$$E ( A ) = ( \begin{matrix}21 \\ 8\end{matrix} ) - ( ( \begin{matrix}20 \\ 8\end{matrix} ) + ( \begin{matrix}18 \\ 7\end{matrix} ) + … + ( \begin{matrix}2 \\ 1\end{matrix} ) ) = 203490 - 168400 = 35090$$

All the symbols with “A” are now encoded/compressed by Encoder 16 suing binomial encoding process. The sequence remaining after the encoding of the first symbol in the data stream is “BRYRNBRRYBRN”. Now the entire process is repeated until the symbol “B” is encoded. Note now that the length of the sequence is reduced to 12 as opposed to the original sequence of length of 20. Using the same technique, the encoded binomial value for the symbol “B” is E(B)=42. Once symbol “B” has been encoded, the remaining sequence is “RYRNRRYRN”. This is now treated as the input data stream, and the sequence first character “R” is encoded, wherein the sequence length is now 9. Using the same technique as discussed previously, the encoded value for E(R)=73. The reduced sequence is now “YNYN”, and the encoding process can be continued in the same way until the entire data stream is encoded. Therefore, it is clear that the additional embodiment of statistical encoder/decoder block 30 is not required in this case a binomial encoding procedure is adopted. The technique of binomial encoding by the encoder 16 provides a highly efficient method of lossless compression.

Using the technique of binomial encoding as described above, optimal output for a given series of a set of symbols forming a data stream can be achieved and also produces efficient context based encoding.

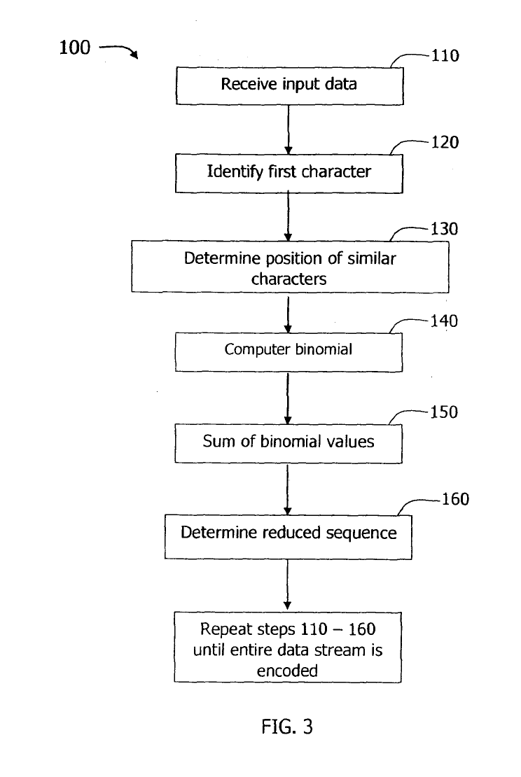

FIG. 3 illustrates an exemplary embodiment of a method 100 which illustrates a manner in which the disclosure may be implemented. At Step 110 input data is received, as mentioned above, the input data is received by the encoder 16, wherein in one embodiment encoder 16 is a binomial encoder. Encoder 16 is capable of processing input data stream contains a sequence of symbols. Once the input data stream is received, the first symbol is determined and encoder 16 scans input stream to determine position in the data stream sequence where the symbol is repeated. For example in the sequence discussed above “ABARAYARANBARRAYBRAN”, the sequence has a length of 20. The first symbol in the sequence is “A”. In the data stream provided as input to encoder there are 8 such sequences of “A,” and the position of the symbol “A” in the remainder of the input data sequence is determined in step 130. For each of these positions for the symbol “A,” the binomial values are computed in the sequence as discussed previously in step 140. Once the binomial values are computed, the sum of these binomials is computed in step 150, as has been described previously. Once the symbol “A” in the sequence is completed, the sequence is now reduced to the following sequence “BRYRNBRRYBRN” as determined in step 160. This sequence is now treated in the same way as described above by repeating the method steps until all the sequences in the data stream are encoded. The process is repeated from steps 110 to 160 until all the symbols in the data stream are encoded/compress, and then the sum of these binomial values is then stored as follows, total length, symbol encoded, count, binomial value, symbol encoded, count, binomial value etc for all the symbols that are encoded. This completes the encoding of the input data stream. After the encoding of the sequence is completed the encoded data will be stored in the form E(sequence)=(20, A, 8, 35090, B, 3, 42, R, 5, 73, Y, 2, 2, N, 2, 1), where the first character 20 represents the length of the sequence. “A” is the first character of the sequence, “8” is the number of occurrences for the symbol “A”, 35090 is the binomial value stored for the symbol “A”, and so on until all symbols in the sequence are encoded in the similar format and E(sequence) will represent the output file.

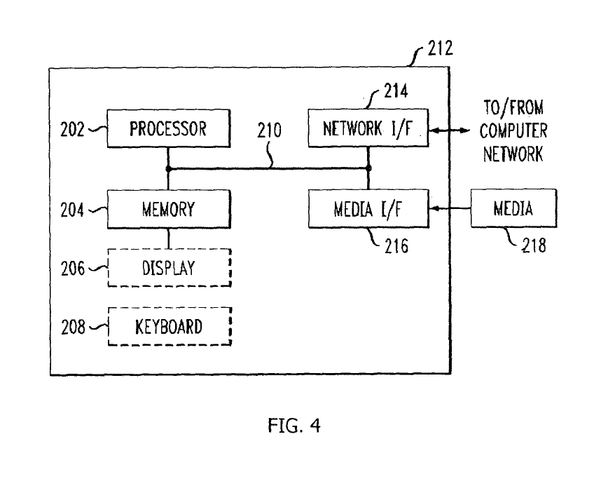

At present, it is believed that the implementation will make substantial use of software running on a general-purpose computer or workstation. With reference to FIG. 4, such an implementation might employ, for example, a processor 202, a memory 204, and an input and/or output interface formed, for example, by a display 206 and a keyboard 208. The term “processor” as used herein is intended to include any processing device, such as, for example, one that includes a CPU (central processing unit) and/or other forms of processing circuitry. Further, the term “processor” may refer to more than one individual processor. In one embodiment, the processor can include the binomial encoding, the statistical encoder is not useful for compression/encoding as the entire sequence is encoded using the binomial encoder. The term “memory” is intended to include memory associated with a processor or CPU, such as, for example, RAM (random access memory), ROM (read only memory), a fixed memory device (for example, hard drive), a removable memory device (for example, diskette), a flash memory and the like. In addition, the phrase “input and/or output interface” as used herein, is intended to include, for example, one or more mechanisms for inputting data to the processing unit (for example, mouse), and one or more mechanisms for providing results associated with the processing unit (for example, printer). The processor 202, memory 204, and input and/or output interface such as display 206 and keyboard 208 can be interconnected, for example, via bus 210 as part of a data processing unit 212. Suitable interconnections, for example via bus 210, can also be provided to a network interface 214, such as a network card, which can be provided to interface with a computer network, and to a media interface 216, such as a diskette or CD-ROM drive, which can be provided to interface with media 218.

Accordingly, computer software including instructions or code for performing the methodologies of the invention, as described herein, may be stored in one or more of the associated memory devices (for example, ROM, fixed or removable memory) and, when ready to be utilized, loaded in part or in whole (for example, into RAM) and executed by a CPU. Such software could include, but is not limited to, firmware, resident software, microcode, and the like.

Furthermore, the disclosure can take the form of a computer program product accessible from a computer-usable or computer-readable medium (for example, media 218) providing program code for use by or in connection with a computer or any instruction execution system. For the purposes of this description, a computer usable or computer readable medium can be any apparatus for use by or in connection with the instruction execution system, apparatus, or device.

The medium can be an electronic, magnetic, optical, electromagnetic, infrared, or semiconductor system (or apparatus or device) or a propagation medium. Examples of a computer-readable medium include a semiconductor or solid-state memory (for example, memory 204), magnetic tape, a removable computer diskette (for example, media 218), a random access memory (RAM), a read-only memory (ROM), a rigid magnetic disk and an optical disk. Current examples of optical disks include compact disk-read only memory (CD-ROM), compact disk-read and/or write (CD-R/W) and DVD.

In one embodiment a data processing system consists of means for encoding/compressing data 16, which is the binomial encoder 16, wherein the means for encoding/compressing data 16 capable of performing the method as discussed previously with respect to FIG. 3.

A data processing system suitable for storing and/or executing program code will include at least one processor 202 coupled directly or indirectly to memory elements 204 through a system bus 210. The memory elements can include local memory employed during actual execution of the program code, bulk storage, and cache memories which provide temporary storage of at least some program code in order to reduce the number of times code must be retrieved from bulk storage during execution.

Input and/or output or I/O devices (including but not limited to keyboards 208, displays 206, pointing devices, and the like) can be coupled to the system either directly (such as via bus 210) or through intervening I/O controllers (omitted for clarity).

Network adapters such as network interface 214 may also be coupled to the system to enable the data processing system to become coupled to other data processing systems or remote printers or storage devices through intervening private or public networks. Modems, cable modem and Ethernet cards are just a few of the currently available types of network adapters.

In any case, it should be understood that the components illustrated herein may be implemented in various forms of hardware, software, or combinations thereof, for example, application specific integrated circuit(s) (ASICs), functional circuitry, one or more appropriately programmed general purpose digital computers with associated memory, and the like. Given the teachings of the invention provided herein, one of ordinary skill in the related art will be able to contemplate other implementations of the components of the disclosure.

Although illustrative embodiments of the invention have been described herein with reference to the accompanying drawings, it is to be understood that the invention is not limited to those precise embodiments, and that various other changes and modifications may be made by one skilled in the art without departing from the scope or spirit of the embodiments of the invention.

1. A method for data compression, the method comprising
receiving as input a data stream, the data stream comprising a sequence of symbols
identifying the first symbol in the data stream;
identifying positions in the data stream where the first symbol is repeated;
encoding all position in the data stream representing the first symbol;
repeating steps (i) to (iv) until the entire data stream is encoded.

2. The method of claim 1, wherein the step of encoding comprises computing a binomial value for each of the repetitive symbol.

3. The method of claim 2, wherein the binomial value for each of the repetitive symbol is computed from the sequence length and the position of the first symbol and each of the repetitive symbols in the sequence.

4. The method of claim 3, wherein the binomial value of the first symbol and each of the repetitive symbols is summed.

5. The method of claim 4, wherein the encoded value comprises the difference between
$$( \begin{matrix}l - 1 \\ t\end{matrix} )$$
and the total sum of the binomial value for the symbol, where “I” is the length of the sequence and “t” is the number of occurrences of the symbol.

6. The method of claim 1, wherein the encoding comprises the total number of symbols in the sequence, the symbol of the sequence for which the binomial value is computed and the binomial value.

7. The method as claimed in any of the preceding claims wherein the encoded data is stored in a predefined format in a file, wherein the file first comprises the length of the sequence, the second character in the file represents the first sequence of the data stream, the third character in the file represents the number of occurrences of the first sequence, the fourth character representing the sum of the binomial value for the first sequence, wherein the second character to fourth character is repeated for all other symbols in the sequence until the entire sequence is represented the above format.

8. A system configured to perform the method as claimed in any of the preceding claims 1 to 7.

9. A system comprising means for binomial encoding/compressing data wherein the means for binomial encoding/compressing data capable of performing the at least one or more of the steps of the method as claimed in any of the preceding claims 1 to 7.
